(19) United States
(12) Patent Application Publication
(10) Pub. No.: US 2020/0136614 A1
(43) Pub. Date: Apr. 30, 2020

(54) INDUCTIVE PROXIMITY SWITCH

(71) Applicant: ZF Friedrichshafen AG, Friedrichshafen (DE)

(72) Inventor: Ajoy PALIT, Bremen (DE)

(73) Assignee: ZF Friedrichshafen AG, Friedrichshafen (DE)

(21) Appl. No.: 16/630,370

(22) PCT Filed: Jun. 20, 2018
(86) PCT No.: PCT/EP2018/066333

§ 371 Date: Jan. 10, 2020

(30) Foreign Application Priority Data
Jul. 13, 2017 (DE) 10 2017 212 052.5

(51) Int. Cl. H03K 17/95; H03K 17/972

(52) U.S. Cl. CPC H03K 17/952; H03K 17/972

(57) ABSTRACT

A binary proximity switch comprises a frequency generator for providing an AC voltage; a coil connected to the AC voltage for generating an alternating magnetic field; an influencing element that is attached such that it can move in relation to the coil and is configured to influence the alternating magnetic field to different extents depending on its distance to the coil; a rectifier for rectifying the AC voltage applied to the coil; a comparator for determining whether or not the rectified voltage exceeds a predetermined threshold value; and an interface for providing a binary signal indicating the determination result.

The invention relates to an inductive position determination. In particular, the invention relates to determining a relative position of a mechanism on board a motor vehicle.

There is a gearshift lever in a motor vehicle that affects a gear selected in a transmission. The gearshift lever can be moved to different positions by the driver, wherein the gearshift lever can be guided in a gate. The position of the gearshift lever is then scanned and processed electrically or electronically. A control unit can then control the transmission on the basis of the driver's desire expressed by the position of the gearshift lever.

The position of the gearshift lever can be scanned in that a permanent magnet is attached to the gearshift lever, and a number of integrated Hall sensors on a console detect the magnetic field of the permanent magnet. The magnet and the sensors are relatively expensive, however. If the gearshift lever is able to assume a larger number of positions, which can each be determined, such an assembly may be uneconomical.

DE 10 2015 200 620 A1 relates to an inductive proximity switch for determining the position of a gearshift lever by means of a number of coils that are attached to a console, and a ferromagnetic and non-conductive positioning element that is attached to the gearshift lever.

The fundamental object of the invention is to create an improved device for inductive position determining. The invention achieves this object by means of a device that has the features of the independent claim. Dependent claims describe preferred embodiments.

A binary proximity switch comprises a frequency generator for an AC voltage; a coil connected to the AC voltage for generating an alternating magnetic field; an influencing element that is attached such that it can move in relation to the coil and is configured to affect the alternating magnetic field to different extents depending on its distance to the coil; a rectifier for rectifying the AC voltage applied to the coil; a comparator for determining whether or not the rectified voltage exceeds a predetermined threshold value; and an interface for providing a binary signal indicating the determination result.

The binary proximity switch can be economically constructed from standard components. The determination of the position of the influencing element can be reliably determined by the binary layout of the proximity switch. An operating element that controls a safety-relevant process, e.g. a gearshift lever for a gear setting of a gear in a drive train of a motor vehicle, can be reliably controlled on the basis of the proximity switch.

The coil is preferably a flat coil. The flat coil can be comprised in particular of a printed circuit. Although a flat coil can only produce a small magnetic field, the circuit can nevertheless be selective enough to distinguish between a “close” and “distant” position of the influencing element. The printed flat coil can be economically provided on a circuit board. This coil structure can be particularly economical, such that a large number of flat coils can be provided economically.

With a flat coil, it is preferred that the influencing element is also flat, such that it can be placed as close as possible to the flat coil. The effect of the alternating magnetic field of the flat coil can thus be maximized. Different embodiments are conceivable for the form of the influencing element. In general, the influencing element can preferably cover a surface area that is at least as large as the surface area of the flat coil.

In a first variation, the influencing element comprises and electrical conductor that draws off energy from the magnetic field through the formation of eddy currents. In this embodiment, the rectified voltage drops when the influencing element approaches the coil. The electric conductor can be economical and robust. By way of example, the conductor can comprise copper or another highly conductive material.

In another variation, the influencing element comprises a magnetically soft and electrically insulating material, in order to locally amplify the alternating magnetic field. As set forth in the invention, “locally” means within a predetermined distance to the coil. In this embodiment, the rectified voltage increases when the influencing element approaches the coil. The change in the rectified voltage when the influencing element approaches the coil can be greater in this embodiment than with the conductor functioning as a damping element in the variation described above. The magnetically soft material can comprise ferrite, for example. A relative permeability can be ca. 10,000 or more. The electrical conductivity is preferably less than 10⁻¹⁰ S/m.

The proximity switch can also comprise a booster for amplifying the rectified voltage before it is provided to the comparator. The booster can be economically designed as an integrated operating booster. The operating booster can be operated in the known regenerative manner, in order to obtain a predetermined amplification factor. In another embodiment, the comparator is likewise designed as an operating booster. As a result of the feedback, the comparator can carry out a hysteresis afflicted comparison. The amount of hysteresis can be set by selecting feedback resistances. Numerous operating boosters can be economically provided in a collective housing.

The rectifier particularly preferably comprises a Schottky diode. The Schottky diode does not have a p-n junction, but instead has a metal semiconductor junction. A threshold voltage at which the diode is activated can therefore be as low as ca. 0.4 V to 0.1 V or even lower in different embodiments. The voltage applied to the coil can therefore be particularly delicately rectified with low losses.

There is preferably also a lowpass filter for smoothing the rectified voltage. The lowpass filter can likewise be economically constructed discretely as an R-C link.

There is also preferably a processing unit that has a further interface, wherein the processing unit is configured to transmit the binary signal via the further interface. The further interface can lead, e.g. to a data bus, e.g. a CAN bus. One or more binary signals from one or more proximity switches can be linked to one another by the processing unit. The result of the linking can be provided via the further interface, e.g. as a data telegram. Error detection or resolution, as well as a potential evaluation of redundant information, can take place in the framework of the linking, for example.

In another embodiment, the comparator comprises an analog-digital converter (analog-to-digital converter, ADC) and a numerical comparator. The ADC can sample the rectified and potentially smoothed voltage in order to numerically compare it with a predetermined threshold value. A hysteresis can be readily obtained through the use of numerous threshold values. There can also be supplementary threshold values that indicate a malfunction when the rectified voltage lies above or below them. If, for example, the rectified voltage drops to zero, there may be short circuit in the region of the coil. If the rectified voltage permanently exceeds a high threshold value, there may be a short circuit in the supply voltage.

Numerous coils with dedicated rectifiers, comparators, and interfaces for each coil are preferred, wherein the influencing element can move along a pathway. It can then pass by the coils such that binary signals to the interfaces indicate a position of the positioning element along the pathway. In this manner, a device for scanning the position of an operating element can be easily and efficiently provided. The influencing element can be attached to the operating element, and the coils can be attached, e.g., to a console. The pathway can have an arbitrary shape, e.g. a line segment, a circular segment, or a combination of numerous geometrical curve segments.

The processing unit described above can comprise the comparator. There can also be a multiplexer that is configured to connect the rectified voltages of numerous coils to the analog-digital converter in a series. The processing unit can form an integrated microcomputer or microcontroller, wherein it can then comprise the analog-digital converter. The multiplexer can be internal or external. A total number of components can be reduced by the multiple use of the analog-digital converter. The advantages of the analog-digital converter can nevertheless be exploited for numerous coils.

The invention shall now be described in reference to the attached figures, in which:

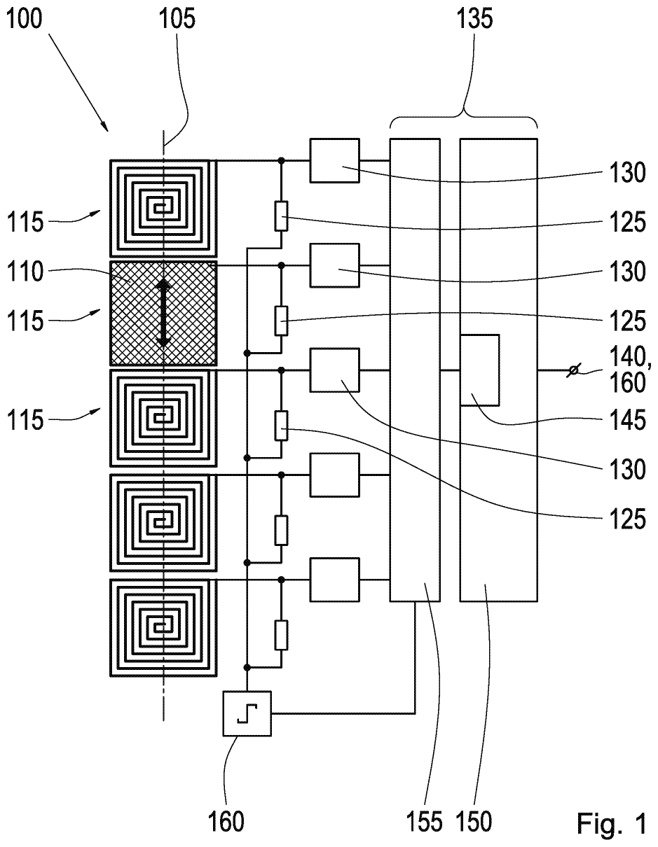

FIG. 1 shows a device for determining the position of a moving element in one embodiment;

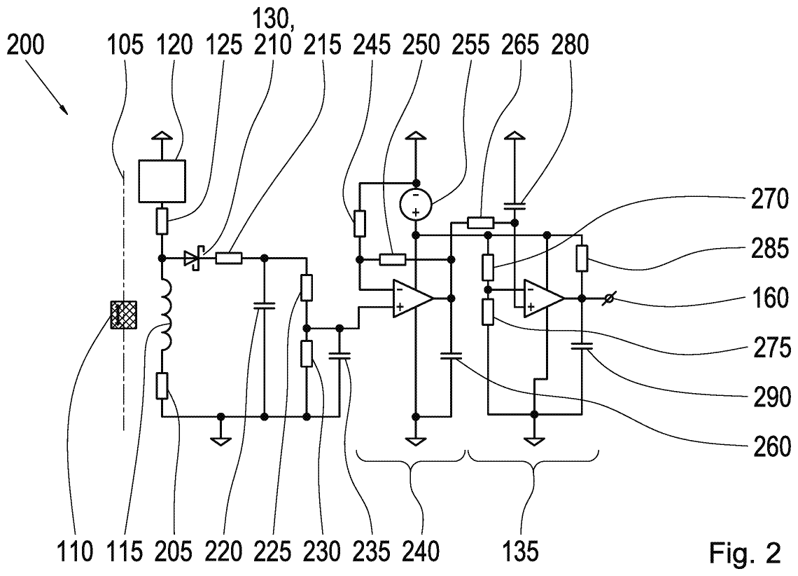

FIG. 2 shows an exemplary circuit for a binary proximity switch configured for use in a device according to FIG. 1;

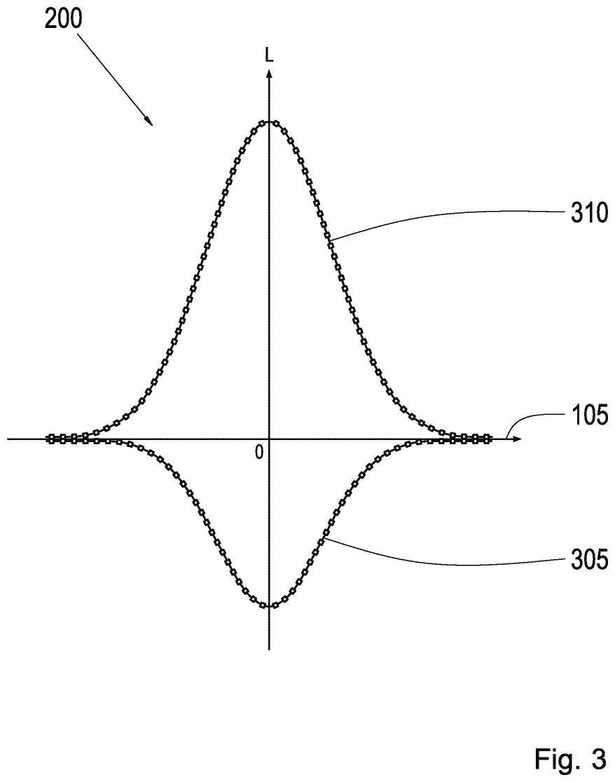

FIG. 3 shows an exemplary correlation between the inductivity of a coil and the distance to an influencing element;

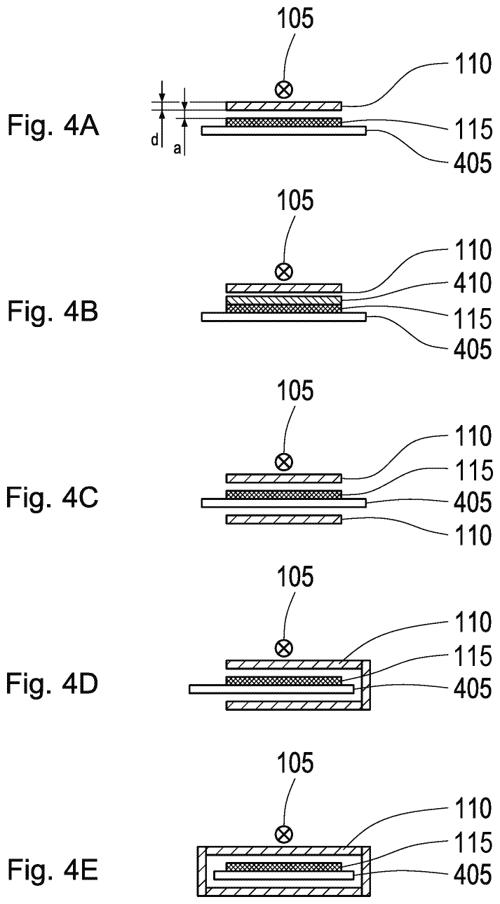

FIG. 4 shows various embodiments of a coil and a moving element for the device in FIG. 1;

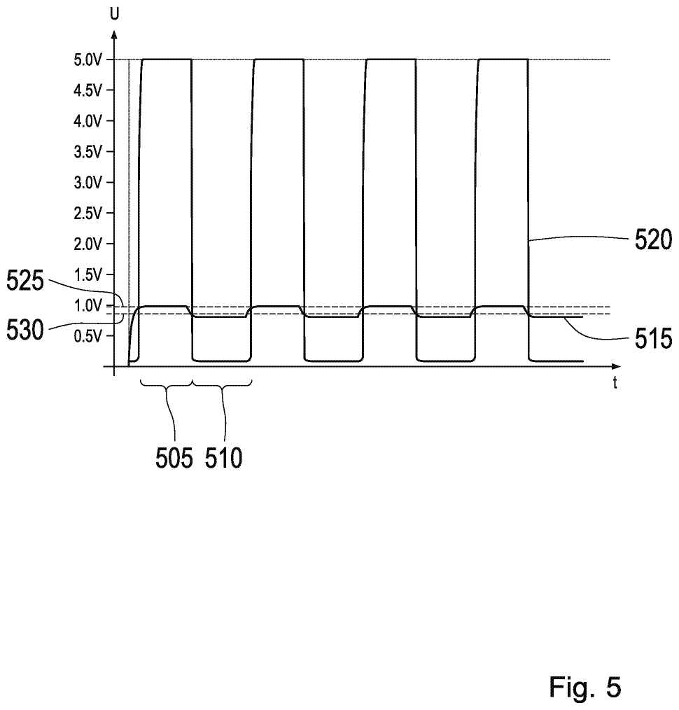

FIG. 5 shows exemplary voltages at the circuit shown in FIG. 2; and

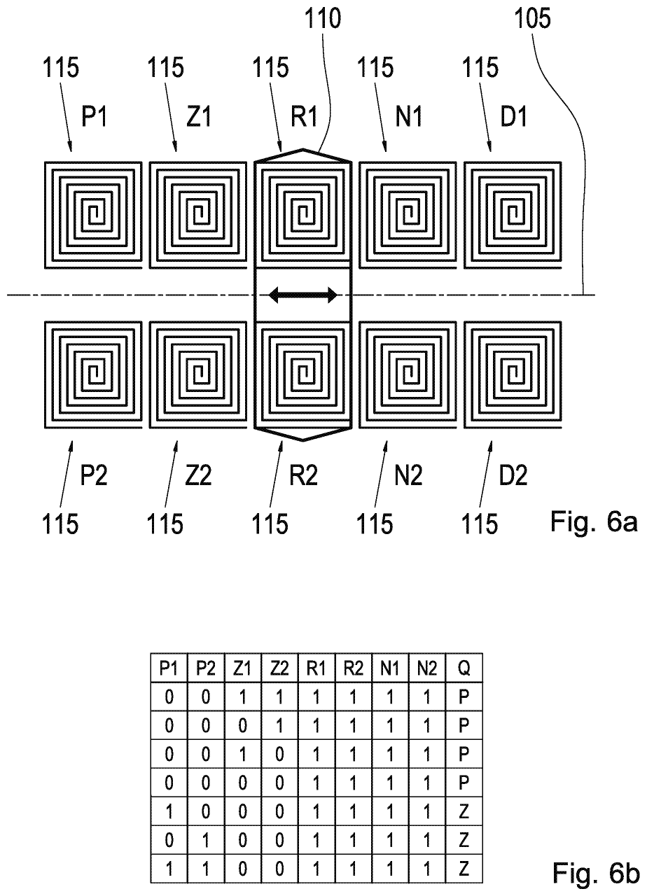

FIG. 6 shows a device for determining the position of a moving element in another embodiment.

FIG. 1 shows a first embodiment of a device 100 for determining the position of a moving element. The device 100 can be used in particular with a gearshift lever or some other input element. The moving element can be moved manually in relation to another element along a predetermined pathway 105. The device 100 comprises an influencing element 110 that can be attached to the moving element, and one or more coils 115 that can be attached to a stationary element. The coils 115 are preferably attached along the pathway 105 such that the influencing element 110 is moved along the pathway 105 as close as possible to the individual coils 115.

The coils 115 can be implemented in particular as flat coils in a printed circuit. The coils 115 can have one or more layers. Typical dimensions of such a coil 115 are ca. 6×6 mm with 12 windings per layer in the printed circuit. The individual layers are typically ca. 70 μm above one another, and ca. 35 μm thick. With a two-layer structure, the unaffected inductance of such a coil 115 can be ca. 1,400 nH.

The influencing element 110 can be attached to preferably the end surface of a coil 115 along the pathway 105. The influencing element 110 is preferably large enough to fully cover the coil 115. A distance to the coil 115 is as small as possible. With a flat coil, the distance can be, e.g., ca. 0.3 to ca. 0.45 mm. A greater distance is also acceptable, in order to take into account an altering effect of a retainer in the assembly, for example. By way of example, the vertical distance to the influencing element 110 can be up to ca. 0.7 mm. The shape of the influencing element 110 can be selected on a practically arbitrary basis. Both the coils 115 and the influencing element 110 are square or rectangular in the depicted embodiment. In another preferred embodiment, the influencing element 110 has rhombic shape, as is indicated by the broken line. While the rhombic influencing element 110 fully covers one of the coils 115, the adjacent coils 115 are partially covered by the corners of the rhombus. The determination of a transition of the influencing element 110 from one coil 115 to the next along the pathway 105 can be facilitated by this.

A frequency generator 120 supplies an AC voltage, which is distributed in the present embodiment to the individual coils 115 by means of resistors 125. In one embodiment, a coil 115 can have a dedicated frequency generator 120. The AC voltage can typically have a frequency of ca. 10 to 15 MHz.

A magnetic field is formed at each coil 115 based on the AC voltage. If the influencing element 110 is close to a coil 115, this changes the inductance of the coil 115. If the influencing element 110 is a damping element that is electrically conductive, the inductance of the coil 115 is reduced when the influencing element 110 is brought closer. If instead, the influencing element 110 is a booster element, which is preferably magnetically soft and electrically insulating, the magnetic field in the region of the coil 115 becomes, in particularly locally, amplified when the influencing element 110 is brought nearer, such that the inductance of the coil 115 increases.

When the damping element 110 is brought nearer, the AC voltage at the coil 115 decreases, and when the booster element 110 is brought nearer, it increases. The AC voltage of a coil 115 is rectified by means of a dedicated rectifier 130, and the rectified voltage is compared with a predetermined threshold value by means of a comparator 135. The comparator 135 is connected to an interface 140 at which a first binary signal can be output when the rectified voltage exceeds the threshold value, and a second binary signal can be output when the voltage lies below the threshold value. The comparator 135 can have an arbitrary construction, e.g. with an operating booster, or discretely by means of a transistor circuit. In the illustrated embodiment, the comparator 135 is formed by an analog-digital converter 145 in conjunction with a processing unit 150. The processing unit 150 can comprise a programmable microcomputer or microcontroller. The analog-digital converter 145 can be comprised by the processing unit 150.

There can be numerous analog-digital converters 145 in the embodiment shown with numerous coils 115, or one analog-digital converter 145 can be connected to one of numerous rectifiers 130 by means of a multiplexer 155. As a result, the rectified voltages on all of the coils 115 can be successively determined by means of one analog-digital converter 145. The numerical result is then compared with a predetermined value representing the threshold value by means of the processing unit 150.

A dedicated comparator 135 assigned to a coil 115 can provide its binary determination result by means of a second interface 160. The second interface 160 can lead to a processing unit 150 and be further processed by it. In the present embodiment, the second interface 160 coincides with the first interface 140, because the processing unit 150 is comprised in the comparator 135.

FIG. 2 shows an exemplary circuit for implementing a binary proximity switch 200, which is preferably configured for use in a device 100 according to FIG. 1. The depicted embodiment illustrates an exemplary possibility for implementing the device 100 with just one coil 115 and without a processing unit 150.

As is the case in the embodiment shown in FIG. 1, the frequency generator 120 is connected to the coil 115 by means of the resistor 125, the second connection of which is connected to a ground by means of another resistor 205. The rectifier 130 is substantially formed here by a Schottky diode 210, e.g. type BAT54. The voltage of the coil 115 rectified by the Schottky diode 210 is conducted by means of an optional decoupling resistor 215 to an optional smoothing capacitor 220, and to another capacitor 235 via a voltage splitter composed of two resistors 225, 230. The voltage splitter can form a lowpass filter with the capacitor 235.

An optional booster 240 amplifies the rectified voltage and provides it to the comparator 135. The booster 240 can be formed as a typical non-inverting booster by means of an operating booster such as type LM321. The amplification factor can be set by means of two resistors 245, 250 in the known manner. In the present case, the operating booster is operated at an exemplary voltage source 255 at typically ca. 5.0 V. The output of the operating booster is smoothed in relation to the ground by means of an optional capacitor 260.

The coupling of the booster 240 to the comparator 135 takes place by means of an optional resistor 265. The comparator 135 is formed here by an operating booster, e.g. type LM2901. A voltage is applied at the inverting input, which can be set with respect to the voltage source 255 by means of a voltage splitter with the resistors 270 and 275. The input signal is conducted to the non-inverting input. In an alternative embodiment, the two inputs can also be exchanged. Optionally, a smoothing of the source voltage can be obtained by means of a capacitor 280. The output of the capacitor 135 can be stabilized by means of another resistor 285 and/or another capacitor 290. The output of the comparator 135 is conducted to the second interface 160.

FIG. 3 shows an exemplary correlation between the inductance of a coil 115 and the distance to an influencing element 110. The distance is plotted horizontally along the pathway 105, and the inductance of the coil 115 is plotted vertically.

A first curve 305 indicates how the inductance decreases from a nominal value when the influencing element 110 in the form of a damping element approaches the coil 115. A maximal decrease of the inductance at a minimum distance can be ca. 20% to 30%. A second curve 310 shows the increase in inductance when the influencing element 110 in the form of a booster element approaches the coil 115. The amplification can reach ca. 40% to 50% at the smallest distance.

Alternatively, a booster element or a damper element can be used for the present invention as the influencing element 110. The values of respective logical threshold values can be estimated from the depiction in FIG. 3.

FIG. 4 shows various embodiments of the arrangements of the coils 115 and the influencing element 110 for the proximity switch 200 shown in FIG. 2 or the device 100 in FIG. 1.

FIG. 4A shows the coil 115 in the form of a flat coil on the surface of a circuit board 405. The circuit board 405 can be made, e.g., of ceramic, glass, polyimide, FR4, or some other suitable carrier material. Alternatively, the coil 115 can also be attached to the surface of an element present on a measurement assembly, e.g. with adhesive. The influencing element 110 is positioned at a predetermined height h above the coil 115. The height h is preferably maintained when the influencing element 110 changes its position in relation to the coil 115. The trajectory 105 is indicated symbolically above the influencing element 110.

FIG. 4B shows a similar embodiment in which, however, there is also a ferromagnetic and electrically insulating element 410 in the region of the coil 115. The element 410 preferably lies between the coil 115 and the influencing element 110, such that the influencing element 110 can also bear on the surface of the element 410. Additionally or alternatively, a ferromagnetic and electrically insulating element 410 can also be attached to the undersurface of the circuit board 405, facing away from the coil 115.

FIG. 4C shows an embodiment with two influencing elements 110 located on different vertical sides of the coil 115 that are mechanically connected to one another in a suitable manner. As a result, the effect on the inductance of the coil 115 is increased, depending on the position of the influencing element 110.

FIG. 4D shows a similar embodiment, in which the influencing element 110 encompasses one side of the circuit board 405 and the coil 115.

FIG. 4E shows an embodiment in which the influencing element 110 encompasses both sides of the circuit board 405 and the coil 115.

FIG. 5 shows exemplary voltages at the circuit of the binary proximity switch 200 from FIG. 2. Time is plotted horizontally, and voltage is plotted vertically. The units shown therein are to be understood purely by way of example.

The coil 115 is alternatingly influenced and not influenced by the influencing element 110 in alternating successive phases 505 and 510. In this illustration, the influencing element 110 can be a booster element, wherein it is close to the coil 115 in the first phase 505, and at a distance thereto in the second phase 510, or a damping element, wherein it is at a distance to the coil 115 in the first phase 505, and close to the coil 115 in the second phase 510. A first curve 515 illustrates the rectified voltage at the coil 115. In the circuit shown in FIG. 2, this voltage can be observed upstream or downstream of the booster 240. Another curve 520 shows a binary signal at the second interface 160. The second curve 520 is determined on the basis of the first curve 515 using two threshold values 525 and 530. The first threshold value 525 is higher than the second threshold value 530, and both threshold values 525, 530 lie between the voltages assumed by the first curve 515 over time. By using two threshold values 525, 530, a circuit hysteresis is obtained; in other embodiments, just one threshold value 525 can be used, and the second curve 520 is determined without hysteresis.

If the first curve 515 exceeds the first threshold value 525, the second curve 520 assumes a first level, corresponding to 0.5 V in this case, which can be interpreted as HIGH, or logical value 1. If the first curve 515 then falls below the second threshold value 530, the second curve then assumes a second level, higher than ca. 0 V in this case, which can be referred to as LOW, or logical value 0. The binary signal at the second interface 160 can be directly evaluated by a logic system, e.g. based on TTL or CMOS, or by means of an analog circuit. It can also be sampled and further processed by a microprocessor. The microprocessor receive the second curves 520 in particular from numerous coils 115, and link them to one another.

FIG. 6 shows a device 600 as a possible embodiment or development of the device 100 in FIG. 1. FIG. 6A shows an arrangement of coils 115 with an influencing element 110 and FIG. 6B shows a truth table for determining the position of the influencing element 110. Evaluation elements from FIGS. 1 and 2 are not shown.

The coils 115 are arranged in pairs, such that they can be influenced by the influencing element 110 in the same manner. For this, the coils can be arranged in two rows along a pathway 105, for example, wherein the influencing element 110 extends over both rows, transverse to the pathway 105. The two rows can lie next to one another, or above one another, for example (cf. FIG. 3).

Exemplary positions of the influencing element 110 are indicated with P, Z, R, N, and D, wherein the coils 115 in the upper row in the illustration in FIG. 6A are assigned to Index 1, and the coils 115 in the lower row are assigned to Index 2. The logical values determined by means of the coils 115 indicate the position of the influencing element 110, wherein a redundant position determination is enabled by means of the two rows.

FIG. 6B shows a truth table for the device 600 shown in FIG. 6A. Only an excerpt of the entire truth table is shown. It is proposed that it be determined that the influencing element 110 is in a position P, Z, R, N, D, when the binary signals of both coils 115 both indicate that the influencing element 110 is close to the coils 115. In the present embodiment, a damping element 110 is used, and a logical signal of 0 indicates the presence or proximity of the influencing element 110.

This approach can be implemented by means of a complete truth table or an algorithm, for example. In both cases the implementation can take place by means of the processing unit 150. The determined position (column Q in the truth table) can be exported via the first interface 140. The first interface 140 can comprise a data interface in particular, e.g. for the CAN bus.

### REFERENCE SYMBOLS

100 device
105 pathway
110 influencing element
115 coil
120 frequency generator
125 resistor
130 rectifier
135 comparator
140 first interface
145 analog-digital converter
150 processing unit
155 multiplexer
160 second interface
200 proximity switch
205 resistor
210 Schottky diode
215 decoupling resistor
220 smoothing capacitor
225 resistor
230 resistor
235 capacitor
240 booster
245 resistor
250 resistor
255 voltage source
260 capacitor
265 resistor
270 resistor
275 resistor
280 capacitor
285 resistor
290 capacitor
305 first curve (damping element)
310 second curve (booster element)
405 circuit board
410 electrically insulating element
505 first phase
510 second phase
515 first curve
520 second curve
525 first threshold value
530 second threshold value
600 device

1. A binary proximity switch comprising:
a frequency generator that provides an AC voltage;
a coil connected to the AC voltage for generating an alternating magnetic field;
an influencing element that is attached such that it can move in relation to the coil and is configured to influence the alternating magnetic field to different extents, depending on a distance to the coil;
a rectifier for rectifying the AC voltage applied to the coil to generate a rectified voltage;
a comparator for determining whether or not the rectified voltage exceeds a predetermined threshold value; and
an interface for outputting a binary signal indicating the determination result.

2. The proximity switch according to claim 1, wherein the coil comprises a flat coil in a printed circuit.

3. The proximity switch according to claim 1, wherein the influencing element comprises an electric conductor for drawing off energy from the alternating magnetic field through formation of eddy currents.

4. The proximity switch according to claim 1, wherein the influencing element comprises a magnetically soft and electrically insulating material for amplifying the alternating magnetic field.

5. The proximity switch according to claim 1, further comprising a booster for amplifying the rectified voltage before it is sent to the comparator.

6. The proximity switch according to claim 1, wherein the rectifier comprises a Schottky diode.

7. The proximity switch according to claim 1, further comprising a lowpass filter for smoothing the rectified voltage.

8. The proximity switch according to claim 1, further comprising a processing unit that has another interface, wherein the processing unit is configured to transmit the binary signal via the other interface.

9. The proximity switch according to claim 1, wherein the comparator comprises an analog-digital converter and a numerical comparator.

10. The proximity switch according to claim 1, further comprising a plurality of coils comprising the coil, wherein the plurality of coils each have dedicated rectifiers, comparators and interfaces, and wherein the influencing element can move along a pathway on which it passes by the plurality of coils, such that the binary signal at the interface indicates a position of a positioning element along a curve.

11. The proximity switch according to claim 10, further comprising:
the comparator further comprising an analog-digital converter and a numerical comparator; and
a multiplexer that is configured to successively connect rectified voltages from the plurality of coils to the analog-digital converter.
